(19) United States
(12) Patent Application Publication
(10) Pub. No.: US 2018/0259582 A1
(43) Pub. Date: Sep. 13, 2018

(54) HOUSEHOLD APPLIANCE

(71) Applicant: BSH Hausgeräte GmbH, Munich (DE)

(72) Inventors: Bernhard Koch, Inzell (DE); Manfred Plankl, Traunwalchen (DE)

(21) Appl. No.: 15/761,118

(22) PCT Filed: Sep. 7, 2016
(86) PCT No.: PCT/EP2016/071005

§ 371 Date: Mar. 19, 2018

(30) Foreign Application Priority Data
Oct. 2, 2015 (DE) 10 2015 219 145.1

(51) Int. Cl. G01R 31/327; H01H 47/00; H05B 1/02

(52) U.S. Cl. CPC G01R 31/3278; H05B 1/0252; H01H 47/002

(57) ABSTRACT

A household appliance includes a mechanical relay, and a switch detection device which is configured to detect a switch of the relay. The switch detection device includes a measuring apparatus to measure an electrical coil current, which flows through the relay when the relay is switched, and an evaluation device to detect the switch of the relay on the basis of the measured coil current. In a method to operate a household appliance, an electric coil current which flows through the relay when the relay is switched is measured, and a switch of the relay and/or a delay time of the relay is detected using the measured coil current. The invention can be advantageously used on cooking devices, in particular ovens, in particular for switching heating elements.

The invention relates to a household appliance, having at least one mechanical relay and a switch detection device for detecting a switch of at least one mechanical relay. The invention also relates to a method for operating a household appliance, which has at least one mechanical relay. The invention can be applied particularly advantageously to cooking appliances, in particular ovens, hobs and/or cookers, in particular for switching heating elements.

In household appliances, electronic circuits with mechanical relays are frequently used to switch heating elements, motors and other electrical loads or consumers. If the service life of a relay has come to an end, a number of switching processes increases with bonding effects (“bonds”) or a contact bonds permanently. This can result for instance in the heating elements or other appliance parts overheating and therefore in hazardous situations. Therefore a heating output in cooktops or ovens can increase automatically, for instance. These bonding effects are currently not captured by the electronics systems in the household appliance. With conventional fault detection scenarios, only one relay activation is monitored, not, however, the switching contact itself. Alternatively, current approaches have reverted back to measuring a contact current or a consumer voltage. However, this is only possible with the use of expensive electronic components, which, in addition to their positioning, requires a large conductor board surface, since the current has to be measured on the mains voltage side and this results in adherence to the requisite spacings.

A zero crossing circuit of the relay can currently also not be effectively realized on account of switch-on and switch-off delays in the relay, which are influenced, for instance, by an installation position, service life, relay coil voltage, ambient temperature and manufacturing tolerances.

DE 195 24 755 A1 discloses a device for monitoring the stroke of switching magnets, which can be used to monitor whether switching magnets have also actually switched after being switched on. The mathematical derivation of the current through the relay coil of the switching magnet is used here as a criterion. The mathematical derivation of the current through the relay coil of the switching magnet can be represented with the aid of a transformer.

WO 2008/064694 A1 discloses a method for detecting the functional capability of an electric relay, which is fed with a control coil current in order to open and/or close an electrical contact device, wherein an armature moves on account of a magnetic field induced by a control coil current. The functional capability is derived from determining a current armature path when the relay is switched on and/or off.

WO 2013/189527 A1 discloses a relay coil, relay contacts and a relay armature actively connected to the relay contacts, and having a monitoring device which is configured to monitor the functional efficiency of the relay. In order to specify such a switching arrangement, with which a preventive check of the relay contacts and of the relay armature for, where appropriate, possible errors is enabled, it is proposed that a current measuring device be provided in the current path of the relay coil and be configured to measure a coil current flowing through the relay coil and to output a current signal specifying the coil current to the monitoring device, and that the monitoring device use the current signal to monitor the functional efficiency of the relay. WO 2013/189527 A1 also relates to a corresponding method for monitoring the functional efficiency of a relay.

US 2011/0228438 A1 discloses a relay failure detection apparatus, which comprises: an opening-closing unit, which is controlled by a relay coil for opening and closing a current path; a detection unit, which detects a current value of a coil current flowing in the relay coil; an opening-closing instruction unit, which outputs an instruction signal to instruct an opening and closing of the opening-closing unit; and a fault detection unit, which detects a fault in the opening-closing unit by using the current value output by the detection unit within a predetermined period of time.

U.S. Pat. No. 6,223,132 B1 discloses an electromechanical relay drive system, which extends a relay service life, by ensuring that during operation of the relay a contact between the contact electrodes at a zero crossing point of the wave form is closed and opened. Relay aging and changes in environmental conditions are dynamically compensated with each actuation of the electromechanical relay, in order to ensure the correct timing of the switching-on and off of the relay with the zero crossing point.

It is the object of the present invention to provide an improved option of operating a household appliance with a mechanical relay.

This object is achieved according to the features of the independent claims. Preferred embodiments can be inferred, in particular, from the dependent claims.

The object is achieved by a household appliance, having at least one mechanical relay and a switch detection device for detecting a switch of at least one mechanical relay, wherein the switch detection device has at least one measuring apparatus for measuring an electrical coil current, which flows through the relay when the relay is switched, and at least one evaluation device for detecting the switch of the at least one relay on the basis of the measured coil current.

This household appliance is advantageous in that it is reliably possible to detect whether and when a contact of the relay actually switches or has actually been switched. Therefore the most frequent indication of failure, namely the bonding of the relay contact, can also be reliably detected. Bonding is critical especially in cooking appliances, since it may result in the heaters activated thereby overheating. Therefore, safety-critical states can be prevented by a relay failing, without the outlay of a switching contact monitoring with respect to load current or load voltage needing to be performed.

A delay time can also be determined with high accuracy after applying a voltage (relay coil voltage) to a relay coil of the relay and the actual switching time instant, which is dependent on an installation position, a remaining service life, the relay coil voltage, an ambient temperature and manufacturing tolerances of the relay etc., and can therefore in practice only be accurately predetermined with difficulty.

The at least one relay can represent part of an electronic circuit. An electronic circuit can be understood to mean in particular a control, regulating and/or amplifier circuit as well as components used herefor.

A relay or mechanical relay is understood in particular to mean a remotely controlled switch which is operated by means of electrical current and acts electromagnetically and has in particular two switching positions. The relay is activated by means of the electronic circuit, for instance, and can switch or optionally open and close at least one current circuit. An electronic switch such as a transistor represents in particular no mechanical relay.

The mechanical relay can be operated such that a coil current in a relay coil generates a magnetic flux through a ferromagnetic core and a likewise ferromagnetic armature disposed thereon and supported moveably. A force effect results on the armature at an air gap, as a result of which this switches one or more contacts. Once the relay coil is no longer excited, the armature can be returned to the starting position by the spring force, for instance.

The contact of the mechanical relay can be embodied as a closer or an operating contact, i.e. the contact is open when the armature fails or the relay coil is currentless and is closed when the armature is attracted or the relay coil has current running through it. However the contact can also be embodied as a closed contact or opener, i.e. it interrupts the current circuit when the relay is in the attracted state. A combination of opener and closer is referred to as changer or changeover contact. A relay can have one or more such contacts. The relay can subsequently be a “closed current relay”, if in the resting state current passes through it and it is attracted. Alternatively it may be an “operating current relay” when it is currentless in the resting state.

The switch detection device can also be referred to inter alia as a “monitoring device”. The household appliance can have at least one mechanical relay, which is not monitored for a switching.

The detection of the switch of the at least one relay can comprise a positive detection of a switch (“switch successful”) and/or a negative detection of a switch (“switch not successful”). The switch can comprise a switching-on and/or off of the relay or establishing and/or detaching the contact of the relay.

The switch detection device and the evaluation device can be different modules or be integrated functionally in a module. The switch detection device and/or the evaluation device can be part or function of the electronic circuit, which also has the at least one mechanical relay. The electronic circuit can therefore have a switch detection and/or evaluation function.

The household appliance is in particular a large household appliance (e.g. a cooking appliance, a laundry care appliance such as a washing machine and/or a tumble dryer, a crockery treatment appliance, such as a dishwasher and/or a crockery disinfection device, a refrigeration appliance such as a refrigerator and/or a freezer etc.). The household appliance is in particular a kitchen appliance (e.g. within the meaning of “white goods”).

The household appliance has in particular an oven or an oven functionality and/or a hob or a hob functionality. The household appliance can therefore be a standalone oven or a cooker as an oven/hob combination. The oven can also have a steam cooking and/or microwave function. The household appliance can have at least one relay-controlled load or at least one relay-controlled consumer, for instance a fan motor, a heating element, etc.

In one embodiment the at least one evaluation device is configured to detect the switch of the at least one associated relay on the basis of a local extreme point in a profile of the measured coil current. This is a particularly safe and simple way of detecting a switch (or a fault) in the relay and/or a delay time. This is utilized such that after applying the relay coil voltage to the relay coil of the relay on account of a mutual induction of the relay coil, a current flow appears, which is only so large after a specific period of time that a magnetic force exerted onto a relay armature is sufficient to close the contact of the relay. During the actual switching time instant of the contact, the mutual induction in the relay coil is influenced or changed by the mechanical movement of the contact armature such that a particularly significant power drop can be measured.

In such cases it can be assumed, for instance, that when the relay voltage U is applied to a relay coil, the theoretical increase in the coil current I(t) corresponds to the formula

I(t)=U/R*(1−e^{-t*R/L}) (1).

The mutual induction of the relay coil is the reason for this current increase. After a specific time, the mutual induction voltage equals zero and only the ohmic resistance of the relay coil is still effective. During the switch-on process, the current increase curve has a strong current drop at the time instant of switching on the contact and a strong current increase at the time instant of switching off the contact, since the movement of the contact armature brings about a change in the mutual induction. This current drop or current increase is so significant that it can be measured with very little component outlay, for instance using an A/D converter of a microcontroller. The minimum of the current drop during switch-on is the time instant at which the relay contact is closed, and the time instant of the actual closure of the contact can subsequently be determined therefrom. When the relay is switched off, the maximum increase in current is the time instant that the switching contact actually opens. If the contact armature is not moved, e.g. due to a bonding effect (“bond”) or another mechanical or electrical defect, there is no current drop or current increase, and a non-switch of the relay can therefore also be detected in the absence of a current drop or current increase.

Consequently in yet another embodiment the at least one evaluation device is configured to detect the switch of the at least one associated relay on the basis of a local minimum (in particular current drop) in the profile of the measured coil current when the relay is switched on and/or on the basis of a local maximum (in particular current increase) in the profile of the measured coil current when the relay is switched off.

If a current drop is measured during the switch-on process, the delay time between the start at which the relay coil voltage is applied and the actual closure of the contact or the contacting of the coil contact can also be easily determined. Analogously the delay time between the switching off of the relay coil voltage and the actual opening of the contact or the release of the coil contact can also be easily determined from a current increase during a switch-off process. In general the delay time between a change in the applied relay coil voltage and the actual switch of the contact can be easily determined.

In a further embodiment the household appliance and in particular its electronic circuit is configured to determine a delay time (duration) between a start at which the relay coil voltage is applied and a time instant of the actual closure of the contact or contacting of the contact elements of the relay and to use this period as an input variable for a phase position-dependent switch of the relay. As a result, consumers present in a current circuit which can be switched by the relay can in turn be switched on and off at specific phase positions. The phase position-dependent switch may comprise in particular a switch of the relay or of the associated at least one consumer. The consumers can be switched on or off in particular at specific phase positions of an alternating supply voltage, e.g. a mains voltage. The phase position can therefore correspond to an alternating voltage (especially mains voltage) phase position. In this respect the household appliance can have a switching time instant controller which is dependent on a mains voltage phase position, in order to switch consumers on or off at specific phase positions. Phase position-dependent switching time instants can therefore be realized by detecting the actual switching time instant. The switching time instant controller can represent part of or a function of the electronic circuit. The switching time instant controller can be a switching time instant regulator.

Expensive relays such as inrush relays etc. can be replaced by the phase position-dependent switching time instant controller using standard relays and costs can thus be saved. Inrush relays were previously used in part for capacitive loads, since they withstand the high switch-on current when capacitances are switched.

In one advantageous development for particularly reliably detecting or determining the actual switching time instant, the household appliance is configured to measure the local extreme point in the current profile (e.g. the current drop) with each switch or switch cycle, since the delay time between applying the relay coil voltage and the actual switching time instant can depend on conditions which change in a time dependent manner, e.g. on the ambient temperature, the remaining service life of the relay etc.

In a further embodiment the household appliance and in particular its electronic circuit is set up to determine a delay time (duration) between a start at which the relay coil voltage is applied to the relay and an actual closure of the associated contact of the relay and to use this period as an input variable for a zero crossing circuit of the relay. An analogous embodiment is that the household appliance and in particular its electronic circuit is configured to determine a delay time (duration) between an end of applying the relay coil voltage and an actual opening of the associated contact of the relay and to use this period as an input variable for a zero crossing circuit of the relay.

The zero crossing circuit may be a special case of the phase position-dependent switching. As a result, the relay contacts switch currentless current circuits, and the service life of the relay thus increases drastically. This results in a significant increase in the service life of relays in particular, which switch high ohmic loads such as e.g. heating elements. Alternatively, more cost-effective relays (for instance standard relays instead of inrush relays) can be used. However, EMC interferences such as “flicker” or “crackle interferences” etc. which may occur when heating elements are switched for instance, can be avoided.

The zero crossing circuit makes it possible in particular for the household appliance (e.g. by means of a corresponding design of the electronic circuit) to be designed such that at least one relay is switched on and/or switched off precisely in the voltage zero crossing of the alternating supply voltage, in particular the mains voltage. With relays which switch high ohmic loads, this results in a significant increase in the service life. Therefore, when the contact of a relay is opened for at least one heating element, for instance, this prevents an electric arc occurring, which could negatively affect the contact elements or the associated contact.

In another embodiment the household appliance, and in particular its electronic circuit, are configured to trigger at least one action when a switch, which is not implemented, and thus a relay defect, of at least one relay are detected.

In one development the action comprises outputting at least one notification. The notification can be indicated in a display in the household appliance, for instance, and/or output wirelessly on a mobile terminal (e.g. smartphone). The notification may be a customer notification, which prompts the customer or user to contact customer services. The notification may alternatively or in addition be communicated directly to customer services, e.g. by way of a corresponding communication interface in the household appliance. The at least one notification can be output for instance by the electronic circuit.

In another embodiment the household appliance and in particular its electronic circuit are configured to bring the electronic circuit into a predefined state when a switch, which is not implemented, of at least one relay (and thus a relay defect) are detected.

Moreover in one embodiment the household appliance is configured to detect the switch of at least one relay on the basis of a test coil current. This is advantageous in that the at least one relay can be checked without an actual load current. This applies in particular in the case when a main switch relay is present.

Moreover in one embodiment the household appliance is a cooking appliance (e.g. oven, a hob and/or a cooker) and at least one relay is provided, in order to switch a current circuit with at least one heating element and/or at least one fan motor. In one development at least one heating element can be operated or energized in a clocked manner by means of the associated relay. In such cases a switch-on duration of the clock is dependent on a set cooking setting or temperature, for instance, and can amount to a number of seconds, for instance.

The object is also achieved by a method for operating a household appliance, which has at least one mechanical relay, wherein with the method an electrical coil current, which flows when the relay is switched, is measured and a switching of the relay is detected on the basis of the measured coil current. The method can be embodied analogously to the household appliance and has the same advantages. Therefore a success or failure of a switching (switching-on and/or switching-off) of the relay and/or a delay time can be determined.

The above-described properties, features and advantages of this invention and the manner in which these are achieved will now be described more clearly and intelligibly in conjunction with the following schematic description of an exemplary embodiment, which will be described in detail making reference to the drawings.

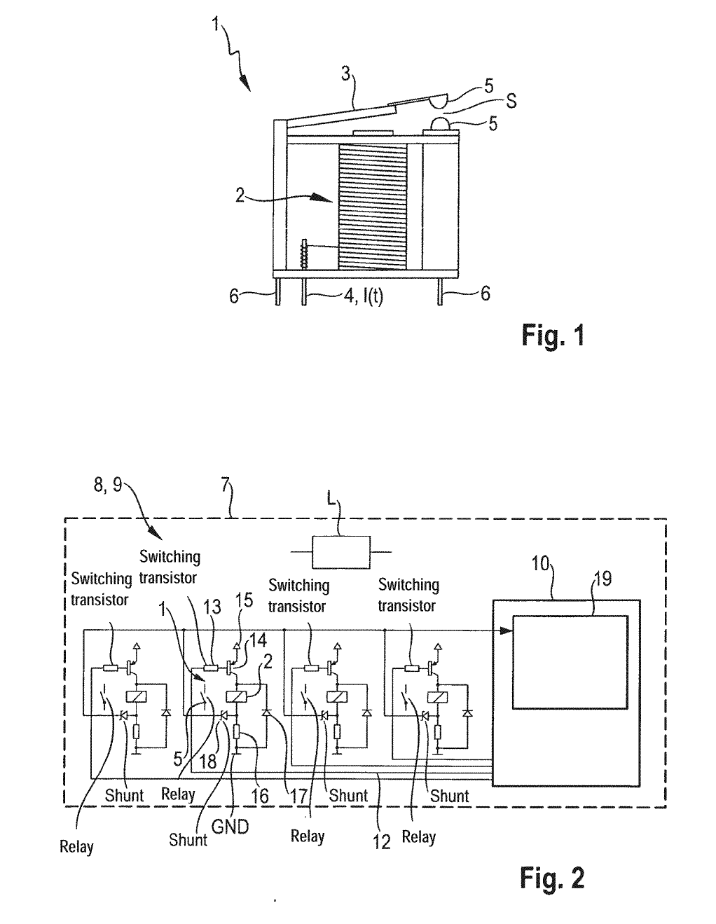

FIG. 1 shows a mechanical relay as a sectional representation; and

FIG. 2 shows a diagram of a household appliance with a switch detection device.

FIG. 1 shows an (electro)mechanical relay 1 with a relay coil 2 and a ferromagnetic armature 3. The relay coil 2 can be applied with a relay coil voltage by way of a switch connection 4 and energized, wherein a coil current I(t) then flows through the switch connection 4. The coil current I(t) generates a magnetic flux in the relay coil 2 through its ferromagnetic core (Fig. above) and the moveably supported, likewise ferromagnetic armature 3. At an air gap S a force effect results on the armature 3, as a result of which this switches one or more contacts with corresponding contact elements 5. Once the relay coil 2 is no longer excited, the armature 3 is returned to the starting position by the spring force. If the contact elements 5 are in contact or if the contact produced therefrom is closed, the relay 1 is also actually closed. The two operating or load connections 6 are then also short-circuited and can close an associated current circuit.

FIG. 2 shows a circuit diagram of a household appliance 7 with a switch detection device 8. The switch detection device 8 is part of an electronics system, electronic module or electronic circuit 9 of the household appliance 7. The electronic circuit 9 can switch relays 1 (here: four) in a targeted manner by way of a microcontroller 10. An associated current circuit of the household appliance 7, which has a load L, can optionally be closed or opened by switching at least one relay 1, for instance. For instance, the household appliance 7 may be or have an oven and/or a hob and the load L may be an electrically operable heating element such as circulating air-, lower- and upper-heating elements, cooking zone heating etc. or a fan motor etc.

The microcontroller 10 can conductively switch a transistor 14 in particular by way of corresponding control lines 12 and series resistors 13, here e.g. by applying a voltage to a base of a pnp bipolar transistor 14 and therefore generating a corresponding switching current. The transistor 14 is connected with its emitter to an equipotential 15, while the collector is connected with one of the load connections 6 of the relay 1. The equipotential 15 can be a predetermined direct voltage potential, for instance. The other load connection 6 is connected in series with ground GND via a shunt 16, so that a voltage is applied between the equipotential 15 and the ground GND. Consequently, with a conductively switched transistor 14, a coil current I(t) can be generated to switch the relay 1, which flows from the equipotential 15 through the pnp bipolar transistor 14, the relay coil 2 and the shunt 16 to the ground GND. Furthermore, a diode 17 is switched antiparallel to the series circuit comprising relay coil 2 and shunt 16. The diode can act as a freewheeling diode, in order to prevent voltage peaks, which are generated when the relay 1 is switched off, from the transistor 14.

To measure the current of the coil current I(t) flowing through the relay coil 2, a “rapid” Schottky diode 18 is used, the anode of which is connected to the load connection 6, which is also connected to the shunt 16. The cathode of the Schottky diode 18 is connected to an input of an A/D converter 19 of the microcontroller 10. If the relay 1 is actuated, the microcontroller 10 can directly receive a current profile which is representative of the coil current I(t). The measuring device can consequently comprise in particular the shunt 16, the Schottky diode 18 and the A/D converter 19.

The microcontroller 10 can also be used as an evaluation device for detecting a switching of the at least one relay 1 on the basis of the measured coil current I(t). Alternatively, other components in the electronic circuit 9 or in the household appliance 7 can serve as the evaluation device. The microcontroller 10 can detect the switching of the at least one associated relay 1, for instance, on the basis of a local minimum when the relay is switched on and/or on the basis of a local maximum when the relay 1 is switched off. The microcontroller 10 can also determine a delay time between applying the equipotential voltage to the relay 1 and a time instant of switching the relay 1 and can use this period as an input variable for a phase position-dependent switching of the relay 1, in particular for a zero crossing circuit. A phase zero crossing signal is required to realize the zero crossing circuit. To this end, a zero crossing signal generator is used, which was previously already known from cooker electronics systems. The zero crossing signal generator can represent part of the electronic circuit 9, for instance, or be functionally integrated into the electronic circuit 9.

If a heating element is to be switched on, for instance, in order to be supplied with a 50 Hz mains frequency, the microcontroller 10 waits for a phase zero crossing signal (which detects a zero crossing of the mains voltage) from the zero crossing signal generator. After receiving this signal, the microcontroller 10 switches the relay 1, e.g. after 10 ms (which corresponds to a time instant of a further zero crossing of the mains voltage) minus a typical delay time of the relay 1 of e.g. 4 ms, in other words in this example 6 ms after receiving the phase zero crossing signal. In such cases the coil current I(t) through the relay coil 2 is measured and the time instant of the current minimum of the current drop is determined. If this current minimum is at precisely the time instant at which the next phase zero crossing of the mains voltage occurs or the next phase zero crossing signal is detected, the relay 1 has switched at precisely the voltage zero crossing. If there is a deviation, however, the time instant of actuating the relay 1 must be corrected on the basis of the measured delay time or its deviation. This results in the relay 1 or its contact elements 5 then switching back in the zero crossing during the next switching process. This adjustment of the control time is therefore particularly advantageous since the delay time of the relay 1 only changes slowly compared with the period duration of the mains voltage of 20 ms. A sudden change in the delay time is thus consequently not expected. A closure of the contact elements 5 in the voltage zero crossing is for instance an easy option of switching capacitive loads or consumers, since during switch-on there is no switch-on current.

Analogously movement is possible when the contact elements 5 are opened. For instance, this is particularly advantageous for ohmic loads L or consumers such as heating elements, so that no electric arcs occur, which could negatively affect the contact elements 5 or the associated contact. If the load L is to be switched off again in the form of a heating element, the microcontroller 10 waits again for the phase zero crossing signal. If this is detected, the voltage of the relay coil 2 is switched off after 10 ms minus an associated stored delay time of the relay 1 (which can be readjusted like the delay time during switch-on). In such cases, the coil current I(t) is measured and the time instant of the current maximum of the local current increase is detected. If this time instant occurs at precisely the next phase zero crossing signal, the contact elements 5 have been opened precisely in the voltage zero crossing. If there is a deviation, the switch-off time of the relay coil voltage is adjusted, so that a reliable zero crossing switching is reached during the next switch-off process. The delay time during switch-on can equate to the delay time during switch-off, or vice versa.

If no current drop and/or no current increase has been detected during switch-on or during switch-off in each case when the coil current I(t) is measured, a defect in the relay 1 e.g. as a result of a “bond”, can be assumed. The microcontroller 10 can then be configured to switch off the main switch relay if a relay fault is detected, in order to bring the household appliance 7, in particular its electronic circuit 9, into a predefined state and/or to output a message about the relay fault to a user and/or to customer services, manufacturer etc.

Naturally, the present invention is not restricted to the exemplary embodiment disclosed.

In general, “a”, “an”, etc. can be understood as singular or plural, in particular in the sense of “at least one” or “one or more”, etc., provided this is not explicitly excluded, e.g. by the expression “exactly one”, etc.

A numerical value can also include the given value as a typical tolerance range, provided this is not explicitly excluded.

### LIST OF REFERENCE CHARACTERS

1 Relay
2 Relay coil
3 Armature
4 Switch connection
5 Contact element
6 Load connection
7 Household appliance
8 Switch detection device
9 Electronic circuit
10 Microcontroller
12 Control line
13 Series resistor
14 pnp bipolar transistor
15 Equipotential
16 Shunt
17 Diode
18 Schottky diode
19 A/D converter of the microcontroller
I Coil current
L Load
S Air gap

1-12. (canceled)

13. A household appliance, comprising:
a mechanical relay; and
a switch detection device configured to detect a switch of the relay, said switch detection device including a measuring apparatus configured to measure an electrical coil current, which flows through the relay when the relay is switched, and an evaluation device configured to detect the switch of the relay on the basis of the measured coil current.

14. The household appliance of claim 13, constructed in the form of a cooking appliance, said relay switching a current circuit with at least one of a heating element and an air motor.

15. The household appliance of claim 13, wherein the evaluation device is configured to detect the switch of the relay on the basis of a local extreme point of a profile of the measured coil current.

16. The household appliance of claim 13, wherein the evaluation device is configured to detect the switch of the relay on the basis of a local minimum of a profile of the measured coil current when the relay is switched on and/or on the basis of a local maximum when the relay is switched off.

17. The household appliance of claim 13, said household appliance being configured to determine a delay time between a start at which a relay coil current is applied to the relay and a time instant of closure of a contact of the relay, and to use the delay time as an input variable for a phase position-dependent switching of the relay.

18. The household appliance of claim 13, said household appliance being configured to determine a delay time between an end at which a relay coil current is applied to the relay and a time instant of opening the contact of the relay, and to use the delay time as an input variable for a phase position-dependent switching of the relay.

19. The household appliance of claim 13, said household appliance being configured in at least one of two ways, a first way in which the household appliance determines a delay time between a start at which a relay coil current is applied to the relay and a time instant of closure of a contact of the relay and uses the delay time as an input variable for a zero crossing circuit of the relay, a second way in which the household appliance determines a delay time between an end at which the relay coil voltage is applied and a time instant of opening the contact of the relay and uses the delay time as an input variable for a zero crossing circuit of the relay.

20. The household appliance of claim 13, said household appliance being configured to trigger an action when detecting that a switching of the relay is not implemented.

21. The household appliance of claim 13, wherein the relay and the switch detection device are part of an electronic circuit, said household appliance being configured to bring the electronic circuit into a predefined state when detecting that the relay has not been switched.

22. The household appliance of claim 13, said household appliance being configured to detect the switch of the relay on the basis of a test coil current.

23. A method for operating a household appliance, said method comprising:
measuring an electrical coil current generated when a mechanical relay of the household appliance is switched; and
detecting a switching of the relay on the basis of the measured coil current.

24. A method for operating a household appliance, said method comprising:
measuring an electrical coil current generated when a mechanical relay of the household appliance is switched; and
detecting a delay time of the relay on the basis of the measured coil current.
